(19) United States
(12) Patent Application Publication
(10) Pub. No.: US 2012/0233831 A1
(43) Pub. Date: Sep. 20, 2012

(54) PHOTOELECTRIC CONVERSION ELEMENT MANUFACTURING APPARATUS

(75) Inventor: Taketo Tsuji, Chiba-shi (JP)

(73) Assignee: FUJI ELECTRIC CO., LTD, Kawasaki-shi, Kanagawa-ken (JP)

(21) Appl. No.: 13/499,567

(22) PCT Filed: Feb. 16, 2011
(86) PCT No.: PCT/JP2011/053205

§ 371 Date: May 24, 2012

(30) Foreign Application Priority Data
Jun. 17, 2010 (JP) 2010-138359

(51) Int. Cl. H05K 13/00

(52) U.S. Cl. 29/33 R

(57) ABSTRACT

Provided is a photoelectric conversion element manufacturing apparatus capable of effectively performing an annealing treatment on a flexible substrate in a small space, minimizing an increase in the area of the apparatus in an installation space and the processing time, ensuring high productivity, and improving the electric characteristics of a photoelectric conversion element. The photoelectric conversion element manufacturing apparatus forms the photoelectric conversion element and a transparent conductive film on a flexible substrate (1) and transports the flexible substrate (1) to a winding chamber (5) so as to wind around a winding roller (8) provided in the winding chamber (5). The winding chamber (5) includes a roller core heater (11), which is a heating mechanism that performs an annealing treatment on the flexible substrate (1) which is being wound after the film forming process.

### TECHNICAL FIELD

The present invention relates to an apparatus for manufacturing a photoelectric conversion element used in a thin film photovoltaic cell, and more particularly, to a photoelectric conversion element manufacturing apparatus that performs an annealing treatment on a photoelectric conversion element on which a transparent conductive film is formed.

### BACKGROUND ART

In recent years, photovoltaic cells have drawn attention as a clean power generating apparatus from an environmental viewpoint. Among the photovoltaic cells, a thin film photovoltaic cell using a photoelectric conversion element including a photoelectric conversion layer which is made of microcrystalline silicon or amorphous silicon (a-Si) has the advantages of the reduction of a silicon raw material, the increase of an area, and mass production, and has increasing importance in order to create a sustainable society. The photoelectric conversion layer of the thin film photovoltaic cell is generally formed by a plasma CVD method. In addition, a compound-based (CIS) photovoltaic cell including a power generating layer made of Cu, In, Ga, Se, or S has been used.

In general, a high-rigidity substrate is used as a thin film laminate substrate, such as a semiconductor thin film. For example, a flexible substrate, such as a resin sheet or a thin stainless steel plate, is used as a photoelectric conversion element substrate used in the photovoltaic cell, in order to improve convenience, such as a light weight and high handleability, increase the area of the substrate, and achieve mass production to reduce costs. Apparatuses for manufacturing the photoelectric conversion element using the flexible substrate are mainly classified into a roll-to-roll type and a stepping roller type. The roll-to-roll manufacturing apparatus continuously forms a plurality of layers on the flexible substrate that is continuously moved through a plurality of deposition chambers. The stepping-roller-type manufacturing apparatus stops the flexible substrate in the deposition chamber once, forms films on the substrate, and transmits the flexible substrate having the films formed thereon from the deposition chamber to the next deposition chamber.

The photoelectric conversion element formed by the above-mentioned process has a problem in that the electrical property thereof is insufficient due to, for example, a defect in the film occurring during a film forming process. Therefore, a method has been proposed which performs an annealing treatment, such as a heat treatment, on a photoelectric conversion element in a thin film photovoltaic cell to remove, for example, residual strain and improve the photoelectric conversion performance.

For example, Patent Document 1 discloses a thin film photovoltaic cell manufacturing method which performs a heat treatment (annealing treatment) on a flexible substrate that has a thin film photoelectric conversion layer formed thereon and is wound around a winding roller in a heating furnace which is installed separately from the roll-to-roll or stepping-roller-type film forming apparatus under constant conditions, thereby improving photoelectric conversion characteristics.

### CITATION LIST

### Patent Document

Patent Document 1: Japanese Patent No. 4082077

### DISCLOSURE OF INVENTION

### Problem that the Invention is to Solve

However, in Patent Document 1, since the heat treatment is performed on the flexible substrate having the thin film photoelectric conversion layer formed thereon in the heating furnace that is installed separately from the manufacturing apparatus forming the thin film, the size of the manufacturing apparatus increases and thus manufacturing costs increase. In addition, it takes time to transport the substrate and increase the temperature of the heating furnace. Therefore, the productivity of the photoelectric conversion element is reduced.

The invention has been made in view of the above-mentioned problems and an object of the invention is to provide a photoelectric conversion element manufacturing apparatus capable of effectively performing an annealing treatment on a flexible substrate in a small space, minimizing an increase in the area of the apparatus in an installation space and the processing time, ensuring high productivity, and improving the electric characteristics of a photoelectric conversion element.

### Means for Solving Problem

In order to solve the above-mentioned problems of the related art, according to an aspect of the invention, there is provided a photoelectric conversion element manufacturing apparatus that forms a photoelectric conversion element and a transparent conductive film on a flexible substrate and transports the flexible substrate to a winding chamber so as to be wound around a winding roller provided in the winding chamber. The photoelectric conversion element manufacturing apparatus includes a heating mechanism that is provided in the winding chamber and performs an annealing treatment on the flexible substrate that is being wound.

In particular, it is preferable that the invention have the following structures.

(1) The heating mechanism is provided in a core of the winding roller.

(2) A non-contact-type heating mechanism that heats the flexible substrate is provided outside the winding roller.

(3) The non-contact-type heating mechanism includes a driving unit that reciprocates the non-contact-type heating mechanism. The driving unit moves the non-contact-type heating mechanism simultaneously with a winding diameter of the flexible substrate wound around the winding roller.

(4) A temperature measuring device that measures at least one of the temperature of the flexible substrate and the temperature of the core of the winding roller is provided in the winding chamber. The temperature measuring device is electrically connected to a temperature control unit that controls the outputs of the heating mechanism and the non-contact-type heating mechanism.

(5) The winding roller includes a rotating unit that rotates the winding roller. The rotating unit and the driving unit of the non-contact-type heating mechanism are electrically connected to a driving control unit that controls a rotational speed of the winding roller and a movement distance of the non-contact-type heating mechanism.

(6) The temperature control unit and the driving control unit are electrically connected to each other through a main control device.

(7) In the winding chamber, the annealing treatment is performed on the flexible substrate in a temperature range of 120° C. or more.

### Advantages of the Invention

As described above, the photoelectric conversion element manufacturing apparatus according to the invention forms a photoelectric conversion element and a transparent conductive film on a flexible substrate and transports the flexible substrate to a winding chamber so as to be wound around a winding roller provided in the winding chamber. A heating mechanism that performs an annealing treatment on the flexible substrate that is being wound is provided in the winding chamber. Therefore, during a process of winding the flexible substrate after the film forming process, it is possible to perform the annealing treatment on the flexible substrate while a film is formed on another portion and it is not necessary to additionally install a heating furnace and a pressure reducing apparatus or a nitrogen introducing apparatus attached to the heating furnace, separately from the manufacturing apparatus. Therefore, according to the manufacturing apparatus of the invention, it is possible to smoothly and reliably manufacture a photoelectric conversion element whose electric characteristics are improved by the annealing treatment and reduce the area of the apparatus in an installation space and the processing time.

In the invention, since the heating mechanism is provided in the core of the winding roller, it is not necessary to add a large heating chamber to the winding chamber and it is possible to rapidly perform the annealing treatment on the flexible substrate that is wound around the core of the winding roller after a film forming process. Therefore, it is possible to improve the electric characteristics of the photoelectric conversion element.

In addition, in the invention, the non-contact-type heating mechanism that heats the flexible substrate is arranged outside the winding roller. Therefore, it is possible to effectively perform the annealing treatment on the flexible substrate after a film forming process.

Furthermore, in the invention, the non-contact-type heating mechanism includes a driving unit that reciprocates the non-contact-type heating mechanism. The driving unit moves the non-contact-type heating mechanism in operative association with the winding diameter of the flexible substrate that is wound around the winding roller. Therefore, it is possible to effectively perform the annealing treatment on the flexible substrate after a film forming process at a high speed and under constant conditions.

In the invention, a temperature measuring device that measures at least one of the temperature of the flexible substrate and the temperature of the core of the winding roller is provided in the winding chamber. The temperature measuring device is electrically connected to a temperature control unit that controls the outputs of the heating mechanism and the non-contact-type heating mechanism. Therefore, it is possible to change the output of the heating mechanism by monitoring the temperature of the flexible substrate after the film forming process and the temperature of the core of the winding roller and performing feedback control through the temperature control unit. It is possible to control the temperature of the flexible substrate after the film forming process and the temperature of the core of the winding roller with high accuracy.

In the invention, the winding roller includes a rotating unit that rotates the winding roller. The rotating unit and the driving unit of the non-contact-type heating mechanism are electrically connected to a driving control unit that controls the rotational speed of the winding roller and the movement distance of the non-contact-type heating mechanism. Therefore, when the temperature of the flexible substrate after the film forming process and the temperature of the core of the winding roller are monitored and feedback control is performed through the temperature control unit, it is possible to change the rotational speed of the winding roller and the movement distance of the non-contact-type heating mechanism, and adjust the transport speed or heating temperature of the flexible substrate. As a result, it is possible to perform a necessary and sufficient annealing treatment on the flexible substrate after the film forming process.

In the invention, the temperature control unit and the driving control unit are connected to each other through a main control device. Therefore, it is possible to achieve highly responsive control.

In the invention, the winding chamber is evacuated, or inert gas, such as nitrogen or argon, is introduced into the winding chamber. In the winding chamber, the annealing treatment the annealing treatment is performed on the flexible substrate in a temperature range of 120° C. or more. Therefore, it is possible to perform a necessary and sufficient annealing treatment on the flexible substrate after the film forming process and manufacture a photoelectric conversion element with good electric characteristics.

### BRIEF DESCRIPTION OF THE DRAWINGS

FIG. 1 is a cross-sectional view schematically illustrating the structure of a photoelectric conversion element manufacturing apparatus according to an embodiment of the invention.

FIG. 2 is a cross-sectional view taken along line A-A of FIG. 1, illustrating a driving unit of a non-contact-type heater in the manufacturing apparatus shown in FIG. 1.

FIGS. 3(a) and 3(b) are diagrams schematically illustrating a state in which the non-contact-type heater shown in FIG. 2 is moved simultaneously with the winding diameter of a flexible substrate wound around a winding roller, wherein

FIG. 3(a) is a diagram illustrating the arrangement of the non-contact-type heaters when the winding diameter is small and FIG. 3(b) is a diagram illustrating the arrangement of the non-contact-type heaters when the winding diameter is large.

FIG. 4 is a diagram schematically illustrating a rotating unit of the winding roller in the manufacturing apparatus shown in FIG. 1.

FIG. 5 is a flowchart illustrating the flow of a control process of changing the transport speed of the flexible substrate in the manufacturing apparatus shown in FIG. 1.

### BEST MODE FOR CARRYING OUT THE INVENTION

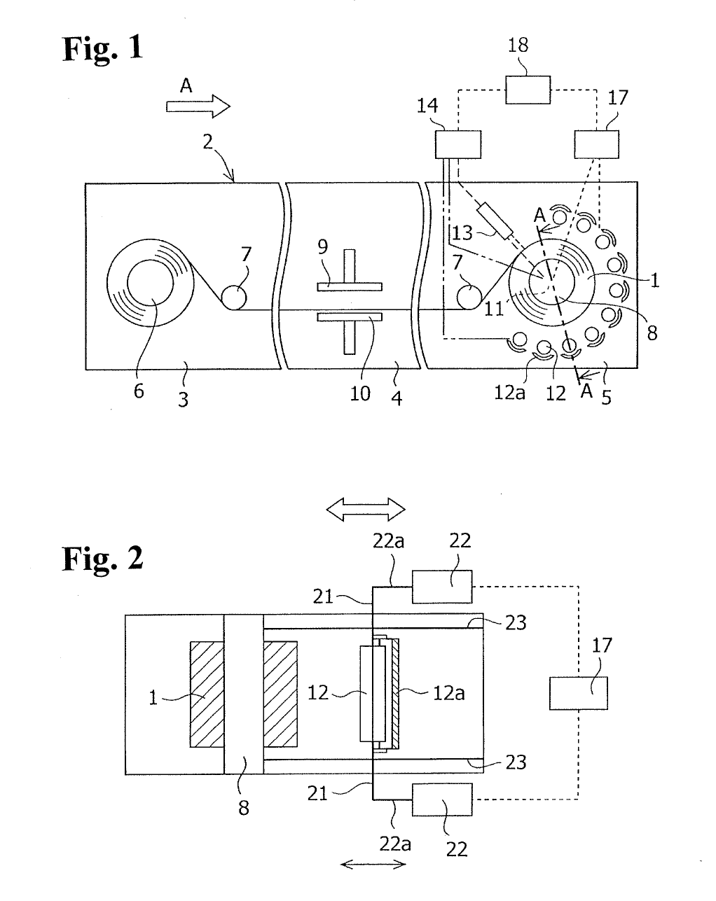

Hereinafter, a photoelectric conversion element manufacturing apparatus according to an embodiment of the invention will be described in detail with reference to the accompanying drawings. FIG. 1 is a cross-sectional view schematically illustrating the structure of the photoelectric conversion element manufacturing apparatus according to the embodiment of the invention.

FIG. 1 shows an embodiment in which a flexible substrate 1 is continuously transported in a roll-to-roll manner. In FIG. 1, the manufacturing apparatus according to this embodiment includes a vacuum chamber 2 that extends in the transport direction of the flexible substrate 1 (the direction of an arrow A). The vacuum chamber 2 includes an unwinding chamber 3, a plurality of deposition chambers 4 (only one deposition chamber is shown in FIG. 1), and a winding chamber 5 that is provided from the upstream side to the downstream side (in FIG. 1, the left to the right). In general, the flexible substrate 1 is made of insulating plastic, such as PET, PEN, PES, acryl, or aramid, or stainless steel.

An unwinding roller 6 for transporting the flexible substrate 1 and a guide roller 7 are provided in the unwinding chamber 3. A winding roller 8 for winding the flexible substrate 1 and a guide roller 7 are provided in the winding chamber 5. The winding chamber 5 is evacuated, or an inert gas, such as nitrogen or argon, is introduced into the winding chamber 5 to create an inert atmosphere.

The flexible substrate 1 is continuously moved from the unwinding roller 6 to the winding roller 8 through the guide roller 7, the deposition chamber 4, and the guide roller 7.

The deposition chamber 4 includes a radio frequency electrode (RF electrode) 9 that receives radio frequency power (RF power) from an external radio frequency power supply through a matching circuit of a matching circuit unit and a cable and a ground electrode 10 that is provided so as to face the radio frequency electrode 9. The radio frequency electrode 9 includes a shower head electrode plate, and a plurality of gas outlets for radially emitting a deposition gas (raw material gas) is formed in the surface of the shower head electrode plate. A heater that heats the transmitted flexible substrate 1 is provided in the ground electrode 10. When a radio frequency voltage is applied to the radio frequency electrode 9, plasma is generated in a discharge space between the radio frequency electrode 9 and the ground electrode 10, and the deposition gas is decomposed and reacts with the substrate. As a result, a photoelectric conversion element and a transparent conductive film are formed on the surface of the flexible substrate 1 transmitted between the electrodes.

In the manufacturing apparatus according to this embodiment, a roller core heater 11, which is a heating mechanism that is used to perform an annealing treatment on the flexible substrate 1 that is being wound after a film forming process, is provided in the core (winding core) of the winding roller 8. The roller core heater 11 has a structure capable of increasing the temperature of the winding roller 8 to a predetermined value and maintaining the temperature. Specifically, the roller core heater 11 is formed by providing a heater inside a roller core that is made of a material, such as stainless steel or aluminum, and heats the substrate from the inside of the core. For example, a sheath heater, an element heater, or a cartridge heater is used as the roller core heater 11, and the roller core heater 11 is supplied with power through a feed through. In addition, a cylindrical heater may be used as the roller core heater, depending on the material forming the flexible substrate to be processed or the structure of the apparatus.

Non-contact-type heaters 12, which are non-contact-type heating mechanisms that heat the flexible substrate 1 having the films formed thereon from the outer circumferential side are arranged at predetermined intervals around the outer circumference of the winding roller 8 so as to respond to a case in which an annealing treatment needs to be performed on the flexible substrate 1 that is being wound at a predetermined temperature or more. A plurality of far-infrared lamp heaters that is arranged in the circumferential direction at predetermined intervals is given as an example of the non-contact-type heaters 12. A reflecting plate 12a is provided outside each lamp heater. The far-infrared lamp heater has low heating efficiency with respect to a material with high reflectance, that is, a material with a small radiation factor. Therefore, it is necessary to use the far-infrared lamp heater suitable for the processing state of the flexible substrate 1 to be used. After the film forming process, an annealing treatment is performed on the flexible substrate 1 at a temperature of 120° C. or more.

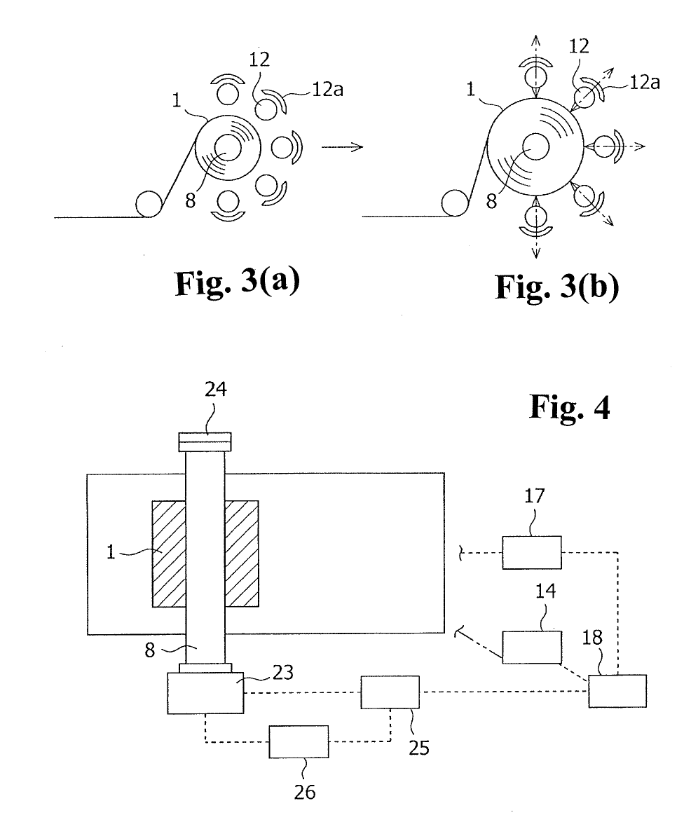

The non-contact-type heater 12 includes a driving unit, such as an actuator that reciprocates the heater, and has a movable structure. In this embodiment, an example of the driving unit of the non-contact-type heater 12 is shown in FIG. 2, which is a cross-sectional view taken along the line A-A of FIG. 1. In FIG. 2, the upper and lower parts of the non-contact-type heater 12 are connected to hydraulic actuators 22 through a connection rod 21 and operation rods 22a. When the operation rods 22a of the actuators 22 are expanded or contracted, the non-contact-type heater 12 is moved in the direction of an arrow. The direction in which the non-contact-type heater 12 is moved is orthogonal to the shaft center of the winding roller 8 in the vertical direction of the non-contact-type heater 12 and the movement of the non-contact-type heater 12 is regulated by guide portions (for example, guide grooves or guide rails) 23 fitted to the connection rod 21. In addition, each actuator 22 is electrically connected to a driving control unit 17, which will be described below. That is, the non-contact-type heater 12 is configured so as to be moved back and forth by the driving unit in the diametrical direction of the flexible substrate 1 after the film forming process in operative association with the winding diameter of the flexible substrate 1 that is wound around the winding roller 8. During the process, the distance between the non-contact-type heater 12 and the flexible substrate 1 is controlled such that the flexible substrate 1 after the film forming process is maintained at a desired temperature. For example, when the winding diameter is small as shown in FIG. 3(a) and is large as shown in FIG. 3(b), the position of the non-contact-type heater 12 is changed depending on a variation in the winding diameter of the flexible substrate 1. In addition, the distance between the flexible substrate 1 wound around the winding roller 8 and the non-contact-type heaters 12 is maintained at a predetermined value and the output of the heaters is controlled such that the amount of heat (heat flux) applied to the flexible substrate is constant. The reason is as follows. When the winding diameter is small, the non-contact-type heaters 12 are arranged close to each other. Therefore, it is possible to effectively heat the flexible substrate with a low heater output.

In this embodiment, a non-contact-type temperature measuring device 13 that measures at least one (in this embodiment, both) of the temperature of the flexible substrate 1 after the film forming process and the temperature of the core of the winding roller 8 is provided in the winding chamber 5. The temperature measuring device 13 is electrically connected to a temperature control unit 14 that controls the output of the roller core heater 11 and the output of the non-contact-type heaters 12.

In this embodiment, the winding roller 8 further includes a rotating unit, such as a motor that rotates the roller. The rotating unit adjusts the rotational speed of the winding roller 8 to change the transport speed of the flexible substrate 1 that is being wound. The rotating unit of the winding roller 8 and the driving unit of each non-contact-type heater 12 are electrically connected to the driving control unit 17 that controls the rotational speed of the winding roller 8 and the movement distance of the non-contact-type heater 12. In addition, the temperature control unit 14 and the driving control unit 17 are electrically connected to each other through a main control device 18. In this embodiment, for example, a rotating unit shown in FIG. 4 is used as the rotating unit of the winding roller 8. One end of the core of the winding roller 8 is directly connected to a rotating shaft of a servo motor 23, which is a rotating mechanism (or one end of the core is indirectly connected to a rubber belt of a mechanism that transmits the rotational motion of the motor), and the other end of the core that is not connected to the rotating mechanism is connected to a rotation support component, such as a bearing 24. Direct connection or indirect connection is selected on the basis of the size of an installation space. The rotating mechanism of the servo motor 23 is electrically connected to the main control device 18 through a rotating unit control device 25. A detecting unit 26, such as an encoder or a tachogenerator that detects the number of rotations of the servo motor 23, is electrically connected between the rotating mechanism of the servo motor 23 and the rotating unit control device 25.

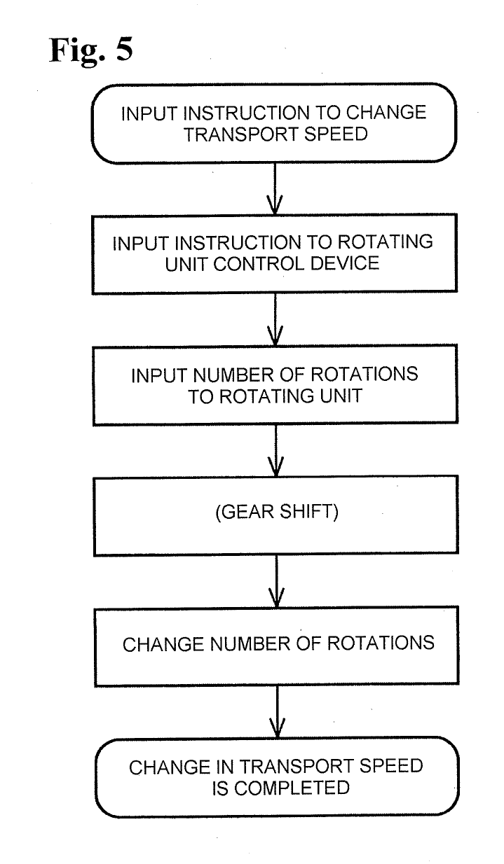

When the servo motor 23, which is the rotating mechanism having the above-mentioned structure, adjusts the rotational speed of the winding roller 8, it is possible to change the transport speed of the flexible substrate 1 that is being wound. That is, as shown in FIG. 5, when information designating the number of rotations is input from the main control device 18 to the servo motor 23 through the rotating unit control device 25 such that the transport speed can be changed, a gear shift is performed. Then, the number of rotations of the winding roller 8 is changed and a change in the transport speed of the flexible substrate 1 is completed. In FIG. 5, the gear shift is performed. However, the gear shift may not be performed according to the structure of the apparatus. A description of the check of the current transport speed or the detection of the transport speed instruction (the detection of the input of an abnormal value) is omitted.

For the control of the rotational speed of the winding roller 8 and the control of the movement distance of the non-contact-type heater 12, the number of rotations of the winding roller 8 increases or decreases and the distance between the non-contact-type heater 12 and the flexible substrate 1 is set to a constant value, or increases or decreases (the distance may be changed depending on the output of the heater), according to the processing conditions shown in the following Table 1. In addition, all of the control units are connected to the main control device 18. Table 1 shows a control method when the output of the heater is constant. The output of the heater is appropriately adjusted according to a material or a target temperature.

TABLE 1

Operation

| | |
|---|---|
| | Distance |
| Processing conditions | between |

| | Heating | Number of | heater and |
|---|---|---|---|
| Heating time | temperature | rotations | substrate |
| Decrease | No change | Increase | Constant |
| Increase | No change | Decrease | Constant |
| No change | Increase | The same | Decrease |
| No change | Decrease | The same | Increase |
| Decrease | Increase | Increase | Decrease |
| Decrease | Decrease | Increase | Increase |
| Increase | Increase | Decrease | Decrease |
| Increase | Decrease | Decrease | Increase |

As such, in this embodiment, the main control device 18 is electrically connected to the temperature control unit 14, the driving control unit 17, and the rotating unit control device 25 and controls each pattern shown in Table 1 on the basis of an input value. That is, the main control device 18 is electrically connected to the temperature measuring device 13 through the temperature control unit 14, feeds back the measurement result of the temperature of the flexible substrate 1 and the temperature of the core of the winding roller 8 by the temperature measuring device 13, and controls the heating time of the non-contact-type heater 12, the distance between the non-contact-type heater 12 and the flexible substrate 1, and the output of each heater.

The exemplary embodiment of the invention has been described above, but the invention is not limited to the above-described embodiment. Various modifications and changes of the invention can be made on the basis of the technical spirit of the invention.

For example, in the above-described embodiment, the roll-to-roll manufacturing apparatus that continuously forms films on the flexible substrate 1 that is continuously moved through the deposition chamber 4. However, the invention can be applied to a stepping-roller-type manufacturing apparatus that temporarily stops the flexible substrate 1 transported into the deposition chamber 4, forms films on the flexible substrate 1, and transports the flexible substrate from the deposition chamber 4 to the next deposition chamber 4. Alternatively, the invention can be applied to a case in which the deposition chamber includes a process, such as a plating process, other than the vacuum process.

In the above-described embodiment, the non-contact-type heaters 12 that heat the flexible substrate 1 from the outer circumferential side of the winding roller 8 are arranged around the outer circumference of the winding roller 8.

However, the non-contact-type heaters 12 may not be provided and only the roller core heater 11 may be provided according to the type of apparatus.

### REFERENCE NUMERALS

1: FLEXIBLE SUBSTRATE

2: VACUUM CHAMBER

3: WINDING CHAMBER

4: DEPOSITION CHAMBER

5: WINDING CHAMBER

6: UNWINDING ROLLER

8: WINDING ROLLER

9: RADIO FREQUENCY ELECTRODE

10: GROUND ELECTRODE

11: ROLLER CORE HEATER (HEATING MECHANISM)

12: NON-CONTACT-TYPE HEATER (NON-CONTACT-TYPE HEATING MECHANISM)

13: TEMPERATURE MEASURING DEVICE

14: TEMPERATURE CONTROL UNIT

17: DRIVING CONTROL UNIT

18: MAIN CONTROL DEVICE

22: ACTUATOR

23: SERVO MOTOR

24: BEARING

25: ROTATING UNIT CONTROL DEVICE

1. A photoelectric conversion element manufacturing apparatus for forming a photoelectric conversion element and a transparent conductive film on a flexible substrate, and then transporting the flexible substrate to a winding chamber to wind around a winding roller provided in the winding chamber,
wherein the winding chamber comprises a heating mechanism performing an annealing treatment on the flexible substrate that is being wound.

2. A photoelectric conversion element manufacturing apparatus according to claim 1, wherein the heating mechanism is provided in a core of the winding roller.

3. A photoelectric conversion element manufacturing apparatus according to claim 1, wherein a non-contact-type heating mechanism is provided outside the winding roller for heating the flexible substrate.

4. A photoelectric conversion element manufacturing apparatus according to claim 3, wherein the non-contact-type heating mechanism includes a driving unit reciprocating the non-contact-type heating mechanism, and
the driving unit moves the non-contact-type heating mechanism in association with a winding diameter of the flexible substrate wound around the winding roller.

5. A photoelectric conversion element manufacturing apparatus according to claim 1, wherein a temperature measuring device is disposed in the winding chamber and measures at least one of a temperature of the flexible substrate and a temperature of the core of the winding roller; and
the temperature measuring device is electrically connected to a temperature control unit controlling the output of the heating mechanism and the non-contact-type heating mechanism.

6. A photoelectric conversion element manufacturing apparatus according to claim 4, wherein the winding roller comprises a rotating unit rotating the winding roller thereof, and
the rotating unit and the driving unit of the non-contact-type heating mechanism are electrically connected to a driving control device controlling a rotational speed of the winding roller and a moving distance of the non-contact-type heating mechanism.

7. A photoelectric conversion element manufacturing apparatus according to claim 5, wherein the temperature control unit and the driving control unit are electrically connected to each other through a main control device.
